(19) United States
(12) Patent Application Publication
(10) Pub. No.: US 2005/0161671 A1
(43) Pub. Date: Jul. 28, 2005

(54) Solid state image pick-up device capable of reducing power consumption

(75) Inventor: Asaba Testsuo, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/042,540

(22) Filed: Jan. 25, 2005

(30) Foreign Application Priority Data
Jan. 28, 2004 (KR) 04-5319

(51) Int. Cl. H01L 29/04

(52) U.S. Cl. 257/59

(57) ABSTRACT

A solid state image pick-up device for reducing power consumption is provided. The solid state image pick-up device includes a plurality of pixels, a plurality of vertical transmitters, and a plurality of output units. The plurality of pixels store signal charges proportionate to an amount of light inputted thereto. The plurality of vertical transmitters receive the signal charges stored in the pixels and transmit the signal charges. The plurality of output units correspond to the plurality of vertical transmitters respectively, convert the signal charges outputted from the corresponding vertical transmitters into signal voltages, and output the signal voltages. Each of the output units includes a floating diffusion layer and an amplifier. The floating diffusion layer converts the signal charges transmitted from the corresponding vertical transmitters into the signal voltages. The amplifier amplifies the signal voltages outputted from the floating diffusion layer and outputs the signal voltages. The solid state image pick-up device does not include a horizontal transmitter, and directly connects a vertical transmitter to an output unit, thereby reducing an operating voltage. As a result, power consumption of the solid state image pick-up device can be reduced.

### BACKGROUND OF THE INVENTION

This application claims the priority of Korean Patent Application No. 2004-5319, filed on Jan. 28, 2004, in the Korean Intellectual Property Office, the contents of which are incorporated herein in their entirety by reference.

1. Field of the Invention

The present invention relates to a solid state image pick-up device such as those used in camcorders and more particularly, to a CCD (charge coupled device) solid state image pick-up device capable of reducing power consumption.

2. Description of the Related Art

Solid state image pick-up devices are used in camera systems such as camcorders, surveillance cameras, and television cameras used for phones. Recently, solid state image pick-up devices are required to be smaller, lighter, and use lower voltages.

FIG. 1 illustrates the structure of a conventional CCD (charge coupled device) solid state image pick-up device. Referring to FIG. 1, the CCD solid state image pick-up device 100 includes a plurality of pixels PD, a plurality of vertical transmitters VCCD1, VCCD2, . . . , VCCDn, a horizontal transmitter HCCD, and an output unit SF.

Each of the pixels PD generates a signal charge SC proportional to an amount of light inputted thereto. Each of the pixels PD includes a photodiode. Signal charges SCs accumulated in the pixels PDs are transmitted to first through n^{th} vertical transmitters VCCD1-VCCDn corresponding to the signal charges SCs. The first through n^{th} vertical transmitters VCCD1-VCCDn carry out shifting operations and transmit the signal charge SC to the horizontal transmitter HCCD. Then, the horizontal transmitter HCCD carries out a shifting operation and transmits the signal charge SC to the output unit SF. The output unit SF that receives the signal charge SC converts the signal charge SC into a signal voltage SV, amplifies the signal voltage SV, and outputs the signal voltage SV. The signal voltage SV outputted from the output unit SF is displayed as an image through signal processing.

FIG. 2 illustrates how a signal charge SC accumulated in a pixel PD of FIG. 1 is transmitted to a vertical transmitter VCCD. Graphs (a) through (c) of FIG. 2 show a potential according to a voltage level of the pixel PD and the vertical transmitter VCCD. A portion indicated as (i) in the middle of the vertical transmitter VCCD is a buried channel through which the signal charge SC from the vertical transmitter VCCD is transmitted to the horizontal transmitter HCCD.

Graph (a) of FIG. 2 illustrates how the signal charge SC is accumulated in the pixel PD. While the signal charge SC is accumulated in the pixel PD, a poly gate electrode (not shown) adjacent to the pixel PD has a negative voltage level, thereby preventing the signal charge SC from draining out to the vertical transmitter VCCD. Graph (a) of FIG. 2 shows the state of the poly gate electrode (not shown) having a negative voltage level between the pixel PD and the buried channel (i) of the vertical transmitter VCCD. In this state, the signal charge SC is accumulated in the pixel PD.

Graph (b) of FIG. 2 illustrates how the signal charge SC accumulated in the pixel PD is transmitted to the vertical transmitter VCCD. Once the signal charge SC is accumulated, a voltage of approximately 15V is applied to the poly gate electrode (not shown) adjacent to the pixel PD. Then, referring to (b) of FIG. 2, the state of the poly gate electrode (not shown) that acted as a barrier preventing the signal charge SC from draining out to the vertical transmitter VCCD is lowered. The signal charge SC accumulated in the pixel PD is transmitted to the buried channel (i) of the vertical transmitter VCCD.

Graph (c) of FIG. 2 illustrates the state of the signal charge SC transmitted to the vertical transmitter VCCD before moving toward the horizontal transmitter HCCD. When the signal charge SC is completely transmitted to the buried channel (i) of the vertical transmitter VCCD from the pixel PD, a negative voltage is again applied to the poly gate electrode (not shown). Therefore, the poly gate electrode (not shown) acts as a barrier between the pixel PD and the vertical transmitter VCCD. The signal charge SC reaches a state in which the signal charge SC can be transmitted to the horizontal transmitter HCCD via the buried channel (i).

FIG. 3 illustrates how the signal charge is transmitted from the vertical transmitter VCCD to the horizontal transmitter HCCD. FIG. 3 shows how a well-known 4-phase vertical transmitter VCCD works. Since four phases PH1, PH2, PH3, and PH4 exist in the vertical transmitter VCCD of FIG. 3, the vertical transmitter is called a 4-phase vertical transmitter VCCD. The vertical transmitter VCCD includes a first poly gate POLY 1 and a second poly gate POLY 2, arranged alternately. The vertical transmitter VCCD controls a potential of the first and the second poly gates POLY 1 and POLY 2, and moves the signal charge SC toward the horizontal transmitter HCCD.

Graph (a) of FIG. 3 shows a state immediately after the signal charge SC is transmitted from the pixel PD to the vertical transmitter VCCD. When a positive voltage is applied to the first poly gate POLY 1 after being applied to the second poly gate POLY 2 where the signal charge SC is accumulated, the potential of the first poly gate POLY1 is lowered, thereby moving the signal charge SC as in (b) of FIG. 3.

Referring to graph (b) of FIG. 3, when a positive voltage is applied to the second poly gate POLY2 after being applied to the first poly gate POLY1, the potential of the second poly gate POLY2 is lowered, thereby moving the signal charge SC as in graph (c) of FIG. 3. Then, a negative voltage is applied to the second poly gate POLY2 where the signal charge SC was initially stored, thereby raising the potential of the second poly gate POLY2.

Referring to graph (c) of FIG. 3, when a positive voltage is applied to the first poly gate POLY1 after being applied to the second poly gate POLY2, the potential of the first poly gate POLY1 to which the positive voltage was applied is lowered, thereby moving the signal charge SC as in graph (d) of FIG. 4. In this way, the potentials of the first and the second poly gates POLY1 and POLY2 are sequentially changed, thereby moving the signal charge SC vertically to be transmitted to the horizontal transmitter HCCD.

Power consumed in a process of outputting the signal charge SC accumulated in the pixel PD to the outside via the vertical transmitter VCCD, the horizontal transmitter

HCCD, and the output unit SF may be expressed as Power=f*C*V² (“f” denotes dynamic frequency, “C” denotes capacitance, and “V” denotes operating voltage). The operating voltage of the vertical transmitter VCCD is high, i.e., in the range of approximately 15V to −7V. However, when the operating voltage of the vertical transmitter VCCD is super XGA (SXGA), power consumption by the vertical transmitter VCCD is not great because there are only about 1000 cycles. By contrast, although the horizontal transmitter HCCD uses a low operating voltage, the capacitance of a capacitor is great, and an operating voltage when transmitting one frame of the signal charge SC is very high. Therefore, power consumption by the horizontal transmitter HCCD is great.

The operating voltage of the output unit SF is about 12V-15V. Since the output unit SF operates with a dynamic frequency of approximately 1.3 million cycles, power consumption by the output unit SF is also great.

That is, most the power used by the solid state image pick-up device 100 of FIG. 1 is used in the horizontal transmitter HCCD and the output unit SF. Therefore, as solid state image pick-up devices become smaller and lighter, and use lower voltages, they are required to use less power.

### SUMMARY OF THE INVENTION

The present invention provides a solid state image pick-up device capable of reducing power consumption.

According to an aspect of the present invention, there is provided a solid state image pick-up device including a plurality of pixels, a plurality of vertical transmitters, and a plurality of output units. The plurality of pixels store signal charges proportionate to an amount of light inputted thereto. The plurality of vertical transmitters receive the signal charges stored in the pixels and transmit the signal charges. The plurality of output units correspond to the plurality of vertical transmitters respectively, convert the signal charges outputted from the corresponding vertical transmitters into signal voltages, and output the signal voltages.

In one embodiment, each of the output units includes a floating diffusion layer and an amplifier. The floating diffusion layer converts the signal charges transmitted from the corresponding vertical transmitters into the signal voltages. The amplifier amplifies the signal voltages outputted from the floating diffusion layer and outputs the signal voltages.

In one embodiment, the amplifier includes an amplifying transistor and a reset transistor. The amplifying transistor includes an amplifying transistor having a gate, a first terminal connected to a first voltage, and a second terminal. The amplifying transistor receives through its gate the signal voltage outputted from the floating diffusion layer, amplifies the signal voltage, and outputs the signal voltage through its second terminal. The reset transistor includes a first terminal connected to the first voltage, a gate to which a reset control signal is applied, and a second terminal connected to the floating diffusion layer. The reset transistor outputs through its second terminal the signal charge accumulated in the floating diffusion layer.

A voltage level of the first voltage can be 3.3V or less. A voltage level of the first voltage may be one of 2.8V and 3.3V. The amplifying transistor and the reset transistor may be NMOS transistors. The amplifying transistor may be an NMOS transistor, and the reset transistor may be a PMOS transistor.

The solid state image pick-up device may further include a plurality of correlated double sampling units, a plurality of converters, and a horizontal shift register. The plurality of correlated double,sampling units respectively correspond to the output units, receive the signal voltages outputted from the corresponding output units, and generate image signals corresponding to the signal voltages. The plurality of converters respectively correspond to the correlated double sampling units and digitize the image signals outputted from the corresponding correlated double sampling units. The horizontal shift register receives digital image signals outputted from the plurality of converters and outputs the digital image signals.

According to another aspect of the present invention, there is provided a solid state image pick-up device including a plurality of image pick-up units, first through n^{th} floating diffusion layers, and first through n^{th} amplifying circuits. The plurality of image pick-up units convert light inputted to the image pick-up units into signal charges and output the signal charges. The first through n^{th} floating diffusion layers receive and accumulate the signal charges and generate signal voltages corresponding to the signal charges. The first through n^{th} amplifying circuits amplify and output the signal voltages, and eliminate the signal charges accumulated in the first through n^{th} floating diffusion layers. The first through n^{th} floating diffusion layers are directly connected to vertical transmitters corresponding to the image pick-up units.

In one embodiment, each of the image pick-up units includes a plurality of pixels and first through n^{th} vertical transmitters. Each pixel stores a signal charge proportionate to an amount of light inputted thereto. The first through n^{th} vertical transmitters receive the signal charges stored in the pixels and output the signal charges.

In one embodiment, each of the first through n-th amplifying circuits comprises: (i) an amplifying transistor having a gate, a first terminal connected to a charge discharging voltage, and a second terminal, the amplifying transistor receiving through its gate the signal voltage outputted from the floating diffusion layer, amplifying the signal voltage, and outputting the signal voltage through its second terminal; and (ii) a reset transistor comprising a first terminal connected to the charge discharging voltage, a gate to which a reset control signal is applied, and a second terminal connected to the floating diffusion layer, the reset transistor outputting through its second terminal the signal charge accumulated in the floating diffusion layer. The amplifying transistor and the reset transistor may be NMOS transistors. The amplifying transistor may be an NMOS transistor, and the reset transistor is a PMOS transistor. A voltage level of the charge discharging voltage may be 3.3V or less. The voltage level of the charge discharging voltage may be 2.8V or 3.3V.

In one embodiment, the image pick-up device can further include: first through n-th correlated double sampling units respectively corresponding to the first through n-th amplifying circuits, the correlated double sampling units receiving the signal voltages outputted from the corresponding first through n-th amplifying circuits, and generating image signals corresponding to the signal voltages; first through n-th converters digitizing the image signals outputted from the corresponding correlated double sampling units; and a horizontal shift register receiving the digital image signals outputted from the first through n-th converters and outputting the digital image signals.

In accordance with another aspect, the invention is directed to a solid state image pick-up device comprising: a plurality of vertical transmitters, each comprising a first poly gate and a second poly gate arranged alternately, each vertical transmitter transmitting a signal charge proportionate to an amount of light; and a plurality of output units converting the signal charges outputted from the plurality of vertical transmitters into signal voltages and outputting the signal voltages.

In one embodiment, each of the plurality of output units comprises a floating diffusion layer converting a signal charge transmitted from a vertical transmitter into a signal voltage; and an amplifier amplifying the signal voltage outputted from the floating diffusion layer and outputting the signal voltage.

In one embodiment, the amplifier comprises (i) an amplifying transistor formed on a P well, the amplifying transistor having a gate connected to the floating diffusion layer and a first terminal connected to a first voltage, and the amplifying transistor amplifying the signal voltage and outputting the signal voltage through a second terminal; and (ii) a reset transistor formed on the P well and comprising a first terminal connected to the first voltage, a gate to which a reset control signal is applied, and a second terminal connected to the floating diffusion layer, the reset transistor outputting the signal charge accumulated in the floating diffusion layer.

In one embodiment, the amplifier is formed on the P well and further comprises a switch transistor outputting the signal voltage outputted from the amplifying transistor or cutting off the signal voltage. In one embodiment, a voltage level of the first voltage is 3.3V or less. The voltage level of the first voltage can be 2.8V or 3.3V.

An N well can be formed on the P well, and a gate, a first terminal and a second terminal of the rest transistor can be formed on the N well.

In one embodiment,the solid state image pick-up device further comprises: a plurality of correlated double sampling units respectively corresponding to the output units, the correlated double sampling units receiving the signal voltages outputted from the corresponding output units and generating image signals corresponding to the signal voltages; a plurality of converters digitizing the image signals outputted from the corresponding correlated double sampling units; and a horizontal shift register receiving the digital image signals outputted from the plurality of converters and outputting the digital image signals.

### BRIEF DESCRIPTION OF THE DRAWINGS

The foregoing and other features and advantages of the invention will be apparent from the more particular description of an embodiment of the invention, as illustrated in the accompanying drawing. The drawing is not necessarily to scale, emphasis instead being placed upon illustrating the principles of the invention. Like reference characters refer to like elements throughout the drawings.

FIG. 1 contains a schematic diagram illustrating the structure of a conventional CCD (charge coupled device) solid state image pick-up device.

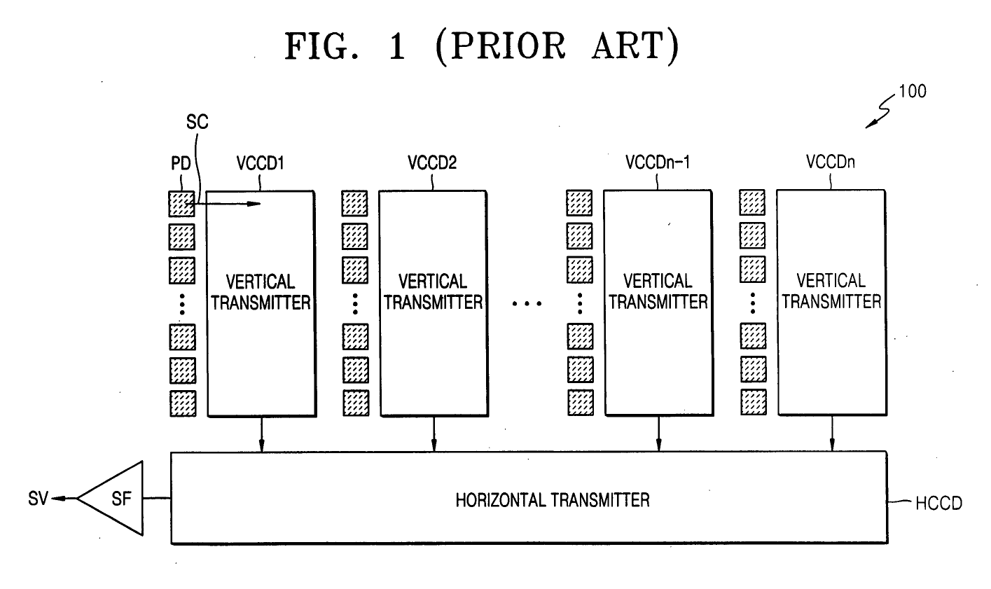

FIG. 2 contains a schematic diagram illustrating how a signal charge accumulated in a pixel of FIG. 1 is transmitted to a vertical transmitter.

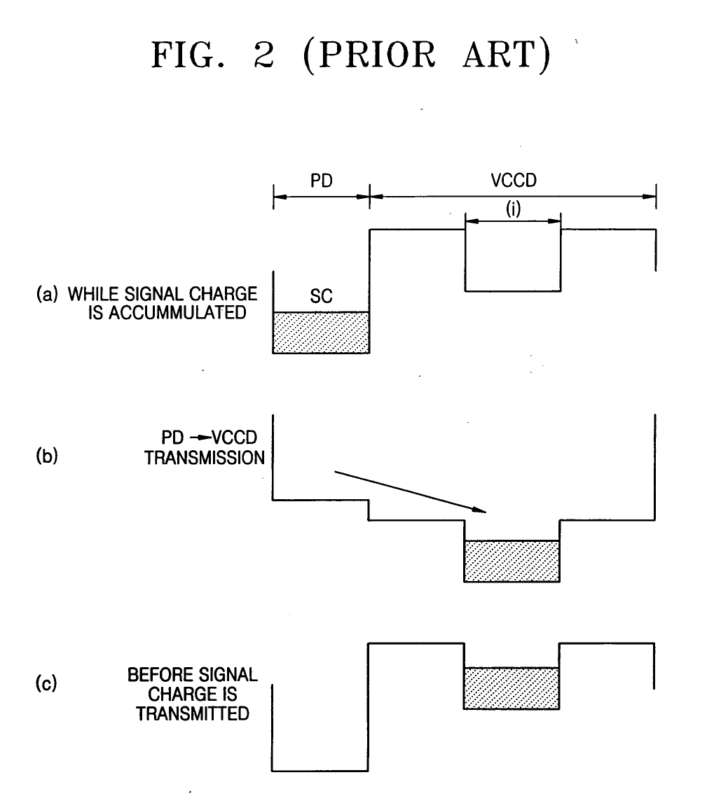

FIG. 3 contains a schematic diagram illustrating how the signal charge is transmitted from the vertical transmitter to a horizontal transmitter in the conventional device of FIG. 1.

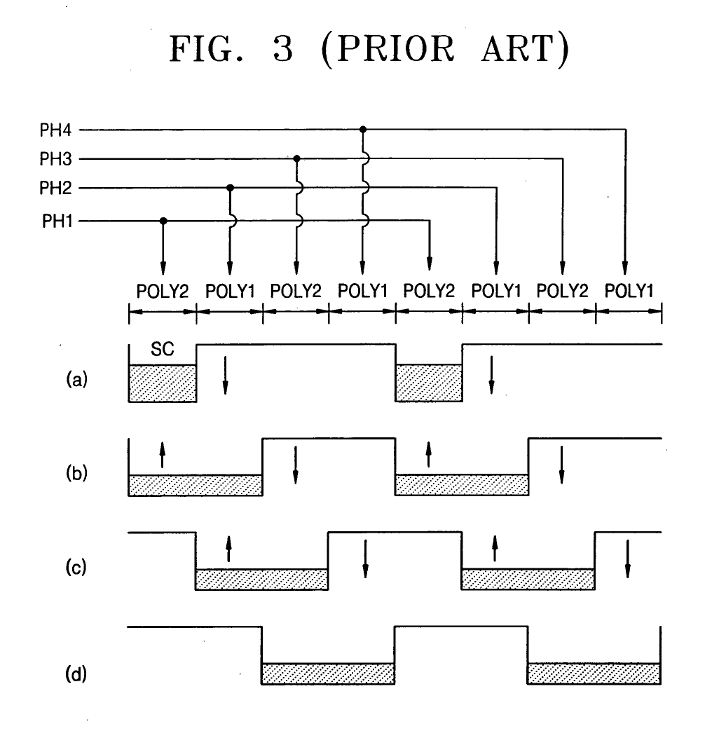

FIG. 4 contains a schematic diagram illustrating the structure of a solid state image pick-up device according to an embodiment of the present invention.

FIG. 5 contains a schematic diagram illustrating the structure of a vertical transmitter and an output unit of FIG. 4.

FIG. 6 contains a schematic diagram illustrating how a signal charge is transmitted from the vertical transmitter to the output unit of FIG. 4.

FIG. 7 contains a schematic diagram illustrating a layout of cross sections of the vertical transmitter and the output unit of FIG. 5.

FIG. 8 contains a schematic diagram illustrating a layout of a reset transistor of FIG. 7 configured to a PMOS transistor.

### DETAILED DESCRIPTION OF THE INVENTION

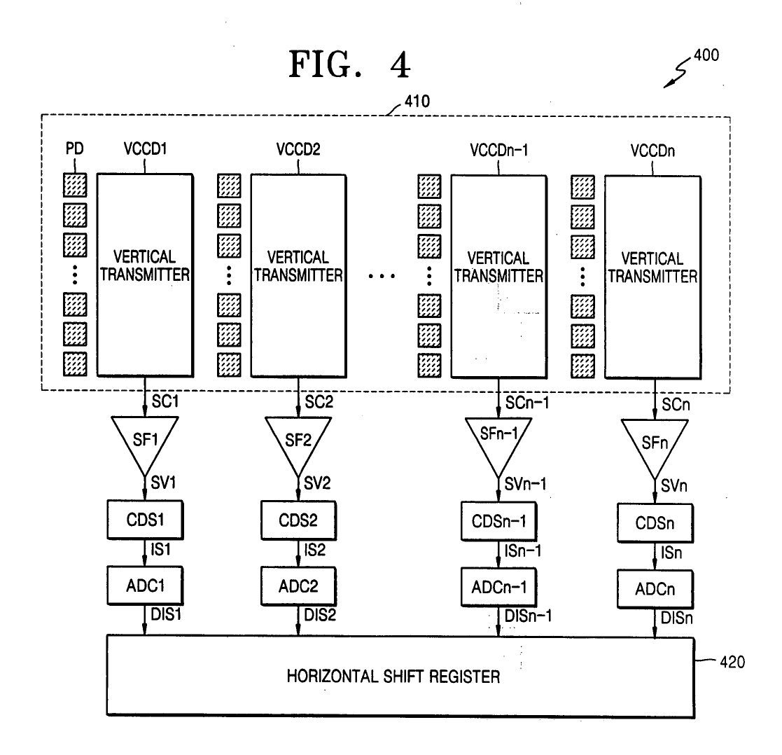

FIG. 4 shows the structure of a solid state image pick-up device according to an embodiment of the present invention. Referring to FIG. 4, the solid state image pick-up device 400 according to the embodiment of the present invention includes a plurality of pixels PD, first through n^{th} vertical transmitters VCCD1-VCCDn, and first through n^{th} output units SF1-SFn.

The plurality of pixels PD store first through n^{th} signal charges SC1-SCn proportionate to an amount of light inputted to the pixels PD. The first through n^{th} vertical transmitters VCCD1-VCCDn receive the first through n^{th} signal charges SC1-SCn stored in the pixels PD and transmit the first through n^{th} signal charges SC1-SCn to the first through n^{th} output units SF1-SFn. The first through n^{th} output units SF1-SFn, which correspond to the first through n^{th} vertical transmitters VCCD1-VCCDn, respectively, convert the first through n^{th} signal charges SC1-SCn outputted from the first through n^{th} vertical transmitters VCCD1-VCCDn, respectively, into first through n^{th} signal voltages SV1-SVn, respectively, and output the first through n^{th} signal voltages SV1-SVn.

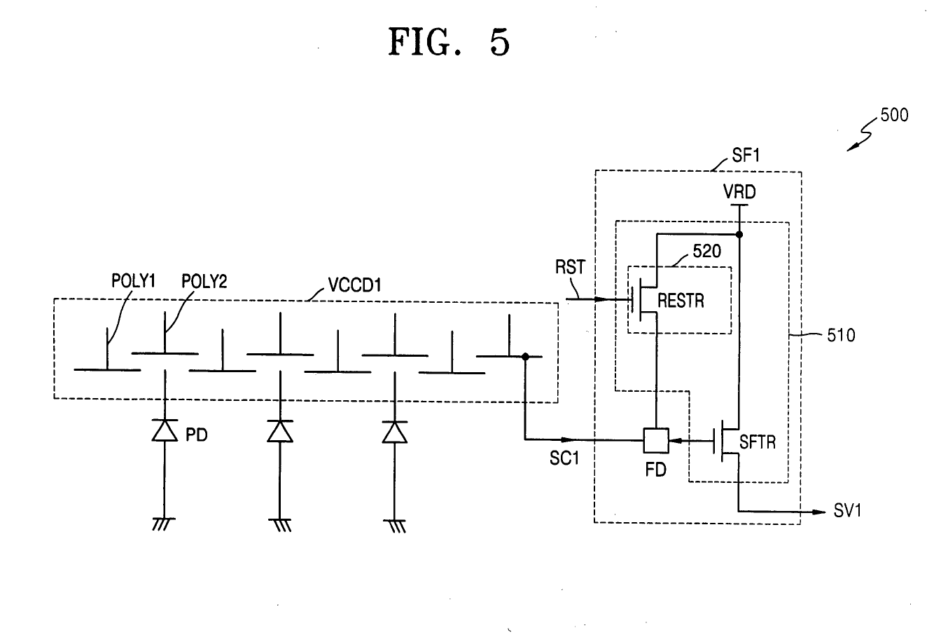

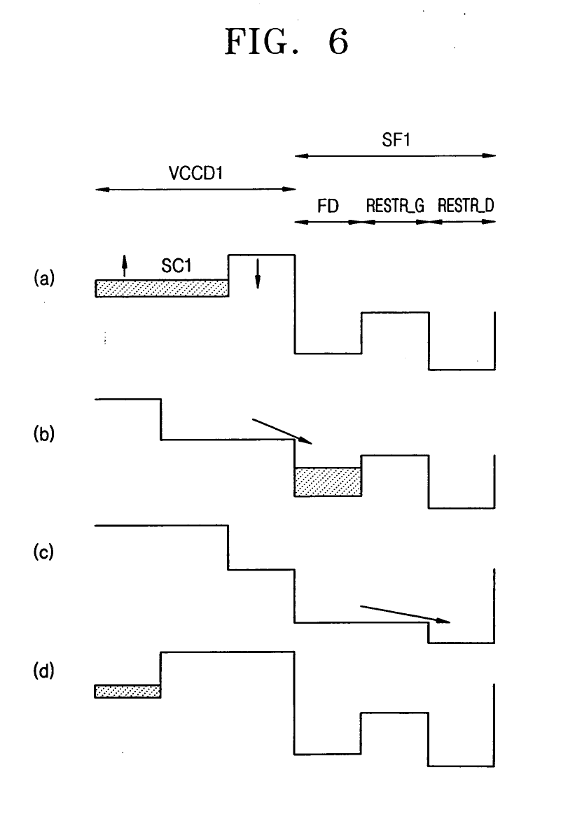

FIG. 5 shows the structure of a vertical transmitter and an output unit of FIG. 4. FIG. 6 illustrates how a signal charge is transmitted from the vertical transmitter to the output unit of FIG. 4.

The operation of the solid state image pick-up device 400 according to the embodiment of the present invention will now be described with reference to FIGS. 4 through 6. FIG. 5 shows the structures of a first vertical transmitter VCCD1 and a first output unit SF1. The structure and operation of the first vertical transmitter VCCD1 and the first output unit SF1 are the same as the second through n^{th} vertical transmitters VCCD1-VCCDn and the second through n^{th} output units SF1-SFn. Hence, the first vertical transmitter VCCD1 and the first output unit SF1 will be used as an example to describe the operations and the structures of the first through n^{th} vertical transmitters VCCD1-VCCDn and the first through n^{th} output units SF1-SFn.

The first vertical transmitter VCCD1 includes a first poly gate POLY1 and a second poly gate POLY2 arranged alternately. Diodes in FIG. 5 are pixels PD. The conventional solid state image pick-up device 100 includes the horizontal transmitter HCCD between the vertical transmitters VCCDs and the output unit SF. However, the solid state image pick-up device 400 according to the embodiment of the present invention does not include the horizontal transmitter HCCD, and the first through n^{th} vertical transmitters VCCD1-VCCDn are directly connected to the first through n^{th} output units SF1-SFn.

Referring to FIG. 5, the first vertical transmitter VCCD1 receives a first signal charge SC1 from the pixels PD and transmits the first signal charge SC1 to the first output unit SF1. The first output unit SF1, which corresponds to the first vertical transmitter VCCD1, converts the first signal charge SC1 outputted from the first vertical transmitter VCCD1 into a first signal voltage SV1, and outputs the first signal voltage SV1.

The first output unit SF1 includes a floating diffusion layer FD and an amplifier 510. The floating diffusion layer FD is connected to the first signal charge SC1. The floating diffusion layer FD converts the first signal charge SC1 transmitted from the first vertical transmitter VCCD1 into the first signal voltage SV1. The level of the first signal voltage SV1 is proportionate to an amount of the first signal voltage SC1 applied to the floating diffusion layer FD. The amplifier 500 amplifies the first signal voltage SV1 outputted from the floating diffusion layer FD and outputs the first signal voltage SV1 to the outside.

The amplifier 500 includes an amplifying transistor SFTR and a re-setter 520. The re-setter 520 includes a reset transistor RESTR. The amplifying transistor SFTR receives through its gate the first signal voltage SV1 outputted from the floating diffusion layer FD. The amplifying transistor SFTR includes a first terminal connected to a first voltage VRD, amplifies the first signal voltage SV1, and outputs the first signal voltage SV1 through a second terminal. In the embodiment illustrated in FIG. 5, the amplifying transistor SFTR is an NMOS transistor.

The reset transistor RESTR includes a first terminal connected to the first voltage VRD. A reset control signal RST is applied to the gate of the reset transistor RESTR. The reset transistor RESTR includes a second terminal connected to the floating diffusion layer FD and outputs the first signal charge SC1 accumulated in the floating diffusion layer FD via the first terminal.

The reset signal RST is a signal that turns on the reset transistor RESTR whenever the first signal voltage SV1 is outputted from the first output unit SF1. As an example, the reset transistor RESTR may be an NMOS transistor. The source of the reset transistor RESTR is connected to the first voltage VRD, and the drain of the reset transistor RESTR is connected to the floating diffusion layer FD.

When the reset transistor RESTR is turned on in response to a reset control signal RST, a waste charge used when the floating diffusion layer FD converts the first signal charge SC1 into the first signal voltage SV1 is discharged through the drain connected to the first voltage VRD.

Graphs (a) through (b) of FIG. 6 show a process of transmitting the first signal charge SC1 stored in the first vertical transmitter VCCD1 to the floating diffusion layer FD of the first output unit SF1. The first signal charge SC1 transmitted to the floating diffusion layer FD of the first output unit SF1 via the first vertical transmitter VCCD1 is moved at voltage levels of 0V and −7V. Therefore, when a constant voltage is applied to the floating diffusion layer FD, all the first signal charge SC1 transmitted via the first vertical transmitter VCCD1 is moved to the floating diffusion layer FD. Referring to graph (c) of FIG. 6, when the gate RESTR_G of the reset transistor RESTR is turned on by the reset signal RST, the waste charge is discharged through the drain RESTR_D of the reset transistor RESTR connected to the first voltage VRD.

In the solid state image pick-up device 400 according to the embodiment of the present invention, the voltage level of the first voltage VRD is less than 3.3V. A voltage connected to a drain of a conventional reset transistor is a DC voltage of approximately 15V.

The conventional output unit SF requires a high operating voltage to convert a signal charge SC outputted from the vertical transmitters VCCDs into a signal voltage SV, amplifies the signal voltage SV, and outputs the signal voltage SV. The single horizontal transmitter HCCD receives signal charges SC transmitted from the plurality of vertical transmitters VCCDs and transmits the signal charges SC to the output unit SF. Therefore, a large amount of signal charge is transmitted from the horizontal transmitter HCCD to the output unit SF, thereby requiring a high operating voltage. However, in the solid state image pick-up device 400 according to the embodiment of the present invention, the first output unit SF1 receives and processes only the first signal charge SC1 outputted from the first vertical transmitter VCCD1 corresponding to the first output unit SF1. Therefore, a high operating voltage is not required.

That is, the respective first through n^{th} output units SF1-SFn just have to process the first through n^{th} signal charges, respectively, which are outputted from the first through n^{th} vertical transmitters VCCD1-VCCDn, respectively. Therefore, the operating voltage of the first through n^{th} output units, that is, the first voltage VRD, can be lowered. More specifically, the first voltage VRD may be 2.8V or 3.3V.

Graph (d) of FIG. 6 illustrates the state of the first signal charge SC1 stored in the first vertical transmitter VCCD1 just before the signal charge is again applied to the first output unit SF1 after the first signal voltage SV1 and the waste charge are discharged through the reset transistor RESTR.

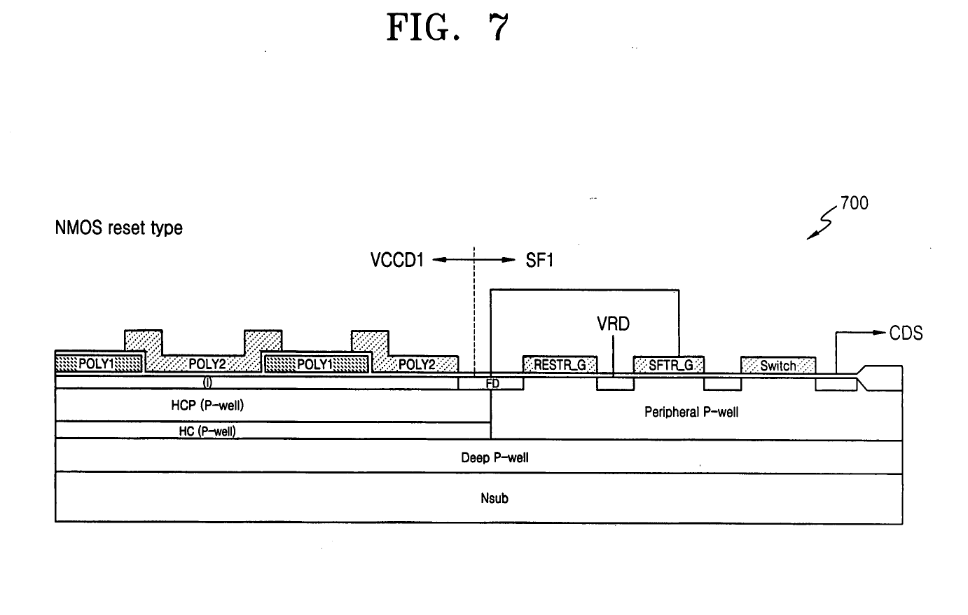

FIG. 7 is a layout of cross sections of the vertical transmitter and the output unit of FIG. 5. Referring to FIG. 7, the first vertical transmitter VCCD1 includes a first poly gate POLY1 and a second poly gate POLY2 arranged alternately, and a buried channel (i). The first signal charge SC1 moved via the buried channel (i) is directly inputted to the floating diffusion layer FD.

The gate RESTR_G of the reset transistor RESTR of the first output unit SF1 is on a P well and the drain RESTR_D to which the first voltage VRD is applied is on the P well. The floating diffusion layer FD is connected to the source of the reset transistor RESTR. The exemplary reset transistor RESTR of FIG. 7 configured in this way is an NMOS transistor. The floating diffusion layer is connected to the gate SFTR_G of the amplifying transistor SFTR. The P well further includes a switch transistor Switch outputting the first signal voltage SV1 outputted via the source of the amplifying transistor SFTR to the outside or cutting off the first signal voltage SV1. When the switch transistor Switch is turned on, the first signal voltage SV1 is outputted to the outside. When the switch transistor Switch is turned off, the first signal voltage SV1 is cut off.

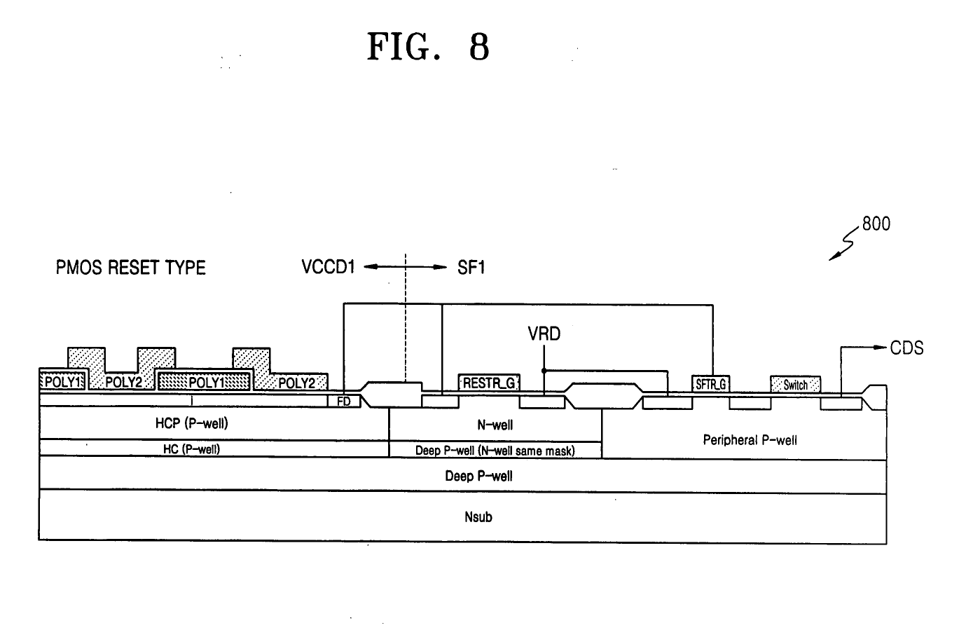

FIG. 8 is a layout of the reset transistor RESTR of FIG. 7 configured as a PMOS transistor. In the solid state image pick-up device 400 according to the embodiment of the present invention, the reset transistor RESTR may be configured as a PMOS transistor. An N well is formed within the P well, and a PMOS reset transistor RESTR is formed in the N well. When the reset transistor RESTR is configured as the PMOS transistor, a feed through effect may be reduced.

Referring again to FIG. 4, the solid state image pick-up device 400 of FIG. 4 may further include first through n^{th} correlated double sampling units CDS1-CDSn, first through n^{th} converters ADC1-ADCn, and a horizontal shift register 420. The first through n^{th} correlated double sampling units CDS1-CDSn correspond to the first through n^{th} converters ADC1-ADCn, respectively. The first through n^{th} correlated double sampling units CDS1-CDSn receive the first through n^{th} signal voltages SV1-SVn outputted from the first through n^{th} output units SF1-SFn, respectively, and generate first through n^{th} image signals IS1-ISn corresponding to the first through n^{th} signal voltages SV1-SVn, respectively. The first through n^{th} correlated double sampling units CDS1-CDSn generate the first through nth image signals IS1-ISn by using a difference between a level of a signal voltage when the reset transistor RESTR is reset and that of a signal voltage generated by a signal charge.

The first through n^{th} converters ADC1-ADCn digitize the first through n^{th} image signals IS1-ISn outputted from the corresponding first through n^{th} correlated double sampling units CDS1-CDSn. The horizontal shift register 420 receives first through n^{th} digital signals DIS1-DISn and transmits the first through n^{th} digital signals DIS1-DISn to the outside.

The solid state image pick-up device 400 according to the embodiment of the present invention includes the same number of the first through n^{th} correlated double sampling units CDS1-CDSn and first through n^{th} converters ADC1-ADCn as the number of the first through nth vertical transmitters VCCD1-VCCDn.

The solid state image pick-up device 400 according to the embodiment of the present invention can utilize the advantages of a CCD and those of a CMOS image sensor (CIS) simultaneously. As for the advantages of the CIS, the solid state image pick-up device 400 according to the embodiment of the present invention does not have a horizontal transmitter and an output unit that require a high operating voltage. Therefore, the solid state image pick-up device 400 may consume less power than the conventional solid state image pick-up device 100.

In addition, there is no heat generated by the horizontal transmitter. Since the first through n^{th} converters ADC1-ADCn may be connected to the rear end of the first through n^{th} correlated double sampling units CDS1-CDSn, the first through n^{th} image signals IS1-ISn can be outputted as the first through n^{th} digital signals DIS1-DISn.

As for the advantages of the CCD, the solid state image pick-up device 400 according to the embodiment of the present invention does not have a metal wiring in an image pick-up device area and may position the first through n^{th} output units SF1-SFn and the reset transistor RESTR outside the image pick-up device area. Therefore, it is possible to manufacture the solid state image pick-up device 400 with a large transistor having no limit to the vertical direction and little flicker noise.

Since a transistor is not included in the image pick-up device area, the problem of hole drain can be eliminated. In the solid state image pick-up device 400 according to the embodiment of the present invention, there is no horizontal transmitter and each of the first through n^{th} vertical transmitters VCCD1-VCCDn is connected to the reset transistor RESTR and the amplifying transistor SFTR. In addition, the output unit of the amplifying transistor SFTR is connected to the correlated double sampling unit as in the CIS. Therefore, the solid state image pick-up device 400 according to the embodiment of the present invention may consume less power than the conventional solid state image pick-up device 100.

As described above, in a solid state image pick-up device according to an embodiment of the present invention, there is no horizontal transmitter and a vertical transmitter is directly connected to an output unit, thereby reducing an operating voltage. As a result, power consumption by the solid state image pick-up device can be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A solid state image pick-up device comprising:
a plurality of pixels storing signal charges proportionate to an amount of light inputted thereto;
a plurality of vertical transmitters receiving the signal charges stored in the pixels and transmitting the signal charges; and
a plurality of output units respectively corresponding to the vertical transmitters, the output units converting the signal charges outputted from the corresponding vertical transmitters into signal voltages, and outputting the signal voltages.

2. The solid state image pick-up device of claim 1, wherein each of the output units comprises:
a floating diffusion layer converting the signal charges transmitted from the corresponding vertical transmitters into the signal voltages; and
an amplifier amplifying the signal voltages outputted from the floating diffusion layer and outputting the signal voltages.

3. The solid state image pick-up device of claim 2, wherein the amplifier Comprises:
an amplifying transistor having a gate, a first terminal connected to a first voltage, and a second terminal, the amplifying transistor receiving through its gate the signal voltage outputted from the floating diffusion layer, amplifying the signal voltage, and outputting the signal voltage through its second terminal; and
a reset transistor comprising a first terminal connected to the first voltage, a gate to which a reset control signal is applied, and a second terminal connected to the floating diffusion layer, the reset transistor outputting through its second terminal the signal charge accumulated in the floating diffusion layer.

4. The solid state image pick-up device of claim 3, wherein a voltage level of the first voltage is 3.3V or less.

5. The solid state image pick-up device of claim 3, wherein a voltage level of the first voltage is one of 2.8V and 3.3V.

6. The solid state image pick-up device of claim 3, wherein the amplifying transistor and the reset transistor are NMOS transistors.

7. The solid state image pick-up device of claim 3, wherein the amplifying transistor is an NMOS transistor, and the reset transistor is a PMOS transistor.

8. The solid state image pick-up device of claim 1, further comprising:
a plurality of correlated double sampling units respectively corresponding to the output units, the correlated double sampling units receiving the signal voltages outputted from the corresponding output units, and generating image signals corresponding to the signal voltages;
a plurality of converters respectively corresponding to the correlated double sampling units, the converters digitizing the image signals outputted from the corresponding correlated double sampling units; and
a horizontal shift register receiving digital image signals outputted from the plurality of converters and outputting the digital image signals.

9. A solid state image pick-up device comprising:
a plurality of image pick-up units converting light inputted to the image pick-up units into signal charges and outputting the signal charges;
first through n-th floating diffusion layers respectively corresponding to the image pick-up units, the first through n-th floating diffusion layers receiving and accumulating the signal charges, and generating signal voltages corresponding to the signal charges; and
first through n-th amplifying circuits amplifying and outputting the signal voltages and eliminating the signal charges accumulated in the first through n-th floating diffusion layers,
wherein the first through n-th floating diffusion layers are directly connected to vertical transmitters corresponding to the image pick-up units.

10. The solid state image pick-up device of claim 9, wherein each of the image pick-up units comprises:
a plurality of pixels, each pixel storing a signal charge proportionate to an amount of light inputted thereto; and
first through n-th vertical transmitters receiving the signal charges stored in the pixels and outputting the signal charges.

11. The solid state image pick-up device of claim 9, wherein each of the first through n-th amplifying circuits comprises:
an amplifying transistor having a gate, a first terminal connected to a charge discharging voltage; and a second terminal, the amplifying transistor receiving through its gate the signal voltage outputted from the floating diffusion layer, amplifying the signal voltage, and outputting the signal voltage through its second terminal; and
a reset transistor comprising a first terminal connected to the charge discharging voltage, a gate to which a reset control signal is applied, and a second terminal connected to the floating diffusion layer, the reset transistor outputting through its second terminal the signal charge accumulated in the floating diffusion layer.

12. The solid state image pick-up device of claim 11, wherein the amplifying transistor and the reset transistor are NMOS transistors.

13. The solid state image pick-up device of claim 11, wherein the amplifying transistor is an NMOS transistor, and the reset transistor is a PMOS transistor.

14. The solid state image pick-up device of claim 9, wherein a voltage level of the charge discharging voltage is 3.3V or less.

15. The solid state image pick-up device of claim 9, wherein a voltage level of the charge discharging voltage is one of 2.8V and 3.3V.

16. The solid state image pick-up device of claim 9, further comprising:
first through n-th correlated double sampling units respectively corresponding to the first through n-th amplifying circuits, the correlated double sampling units receiving the signal voltages outputted from the corresponding first through n-th amplifying circuits, and generating image signals corresponding to the signal voltages;
first through n-th converters digitizing the image signals outputted from the corresponding correlated double sampling units; and
a horizontal shift register receiving the digital image signals outputted from the first through n-th converters and outputting the digital image signals.

17. A solid state image pick-up device comprising:
a plurality of vertical transmitters, each comprising a first poly gate and a second poly gate arranged alternately, each vertical transmitter transmitting a signal charge proportionate to an amount of light; and
a plurality of output units converting the signal charges outputted from the plurality of vertical transmitters into signal voltages and outputting the signal voltages.

18. The solid state image pick-up device of claim 17, wherein each of the plurality of output units comprises:
a floating diffusion layer converting a signal charge transmitted from a vertical transmitter into a signal voltage; and
an amplifier amplifying the signal voltage outputted from the floating diffusion layer and outputting the signal voltage.

19. The solid state image pick-up device of claim 18, wherein the amplifier Comprises:
an amplifying transistor formed on a P well, the amplifying transistor having a gate connected to the floating diffusion layer and a first terminal connected to a first voltage, and the amplifying transistor amplifying the signal voltage and outputting the signal voltage through a second terminal; and
a reset transistor formed on the P well and comprising a first terminal connected to the first voltage, a gate to which a reset control signal is applied, and a second terminal connected to the floating diffusion layer, the reset transistor outputting the signal charge accumulated in the floating diffusion layer.

20. The solid state image pick-up device of claim 19, wherein the amplifier is formed on the P well and further comprises a switch transistor outputting the signal voltage outputted from the amplifying transistor or cutting off the signal voltage.

21. The solid state image pick-up device of claim 19, wherein a voltage level of the first voltage is 3.3V or less.

22. The solid state image pick-up device of claim 19, wherein a voltage level of the first voltage is one of 2.8V and 3.3V.

23. The solid state image pick-up device of claim 19, wherein an N well is formed on the P well, and a gate, a first terminal and a second terminal of the rest transistor are formed on the N well.

24. The solid state image pick-up device of claim 17, further comprising:
a plurality of correlated double sampling units respectively corresponding to the output units, the correlated double sampling units receiving the signal voltages outputted from the corresponding output units, and generating image signals corresponding to the signal voltages;
a plurality of converters digitizing the image signals outputted from the corresponding correlated double sampling units; and
a horizontal shift register receiving the digital image signals outputted from the plurality of converters and outputting the digital image signals to the outside.
